(19) United States
(12) Patent Application Publication
(10) Pub. No.: US 2019/0382617 A1
(43) Pub. Date: Dec. 19, 2019

(54) POLYSILSESQUIOXANE RESIN COMPOSITION AND LIGHT-SHIELDING BLACK RESIST COMPOSITION CONTAINING SAME

(71) Applicant: LTC CO., LTD., Gyeonggi-do (KR)

(72) Inventors: Jun Young KIM, Gyeonggi-do (KR); Hwa Young KIM, Gyeonggi-do (KR); Ho Sung CHOI, Gyeonggi-do (KR)

(21) Appl. No.: 15/999,725

(22) PCT Filed: Sep. 9, 2016
(86) PCT No.: PCT/KR2016/010133

§ 371 Date: Aug. 20, 2018

(30) Foreign Application Priority Data
Feb. 19, 2016 (KR) 10-2016-0019718

(51) Int. Cl. C09D 183/08; C08G 77/04; C09D 7/61; C09D 7/40; C09D 7/45; H01L 27/32; G02B 5/00; G02F 1/1335; H01L 23/31; H01L 23/29; H01L 51/00; G03F 7/075; G06F 3/041

(52) U.S. Cl. CPC C09D 183/08; C08G 77/80; C09D 7/61; C09D 7/67; C09D 7/68; C09D 7/45; H01L 27/3246; G02B 5/003; G02F 1/133512; H01L 27/3258; H01L 23/3171; H01L 23/296; H01L 27/3272; H01L 51/0094; G03F 7/0757; G06F 3/041; C08G 77/045

(57) ABSTRACT

The present invention relates to a polysilsesquioxane resin composition having a high heat resistance and low dielectric constant and applicable to a liquid crystal display, an OLED, a touch panel, electronic paper, a flexible display, etc. and a black resist composition for light-shielding comprising the same. More specifically, the present invention relates to a light-shielding black resist composition having high heat resistance and low dielectric characteristics, which comprises: 1) a polysilsesquioxane random copolymer resin composition, which comprises a polar heterocyclic structure and can be cured by UV rays; 2) a carbon black dispersion liquid prepared by dispersing and coating in the polysilsesquioxane resin; and 3) a photoinitiator. The black resist resin composition of the present invention has excellent heat resistance even in a post process at high temperature of at least 350° C., no optical density (O.D.) deterioration, and can satisfy low dielectric properties at the same time, compared with conventional acrylic or cardo-based black resist.

### TECHNICAL FIELD

The present invention relates to a polysilsesquioxane resin composition and a black resist composition for light-shielding comprising the same and more specifically, to the black resist composition for light-shielding, which has excellent heat resistance in even post-process at a high temperature and low dielectric performance applicable to a color filter on TFT (COT) process, a cover glass-integrated touch panel, an OLED, and a flexible display.

### BACKGROUND ART

Recently, as liquid crystal displays, OLEDs, touch panels, electronic paper and flexible display devices have improved, the need for high performance materials for supporting it has been increasing. Korean patent publication No. 10-2005-0085668 discloses that the conventional black resist for a color filter substrate is prepared in a separate process from an ultra-thin film transistor (TFT) substrate for controlling electrical characteristics, so that because the requirements for heat resistance and permittivity are not high and there is no restriction on the standardized curing process at 230° C. and low dielectric properties, general acryl or cardo-based binder resin is used. Also, acryl or cardo-based binder is used as a binder for dispersing in the production of black pigment dispersions which is added for light-shielding effect in the conventional technique.

However, recently, the cover glass-integrated touch panel requires low dielectric insulating properties because a black resist and a transparent electrode or a metal electrode are in contact with each other, and a high heat resistance property of at least 350° C. so as to withstand the subsequent high temperature deposition process. In addition, in the case of an OLED, a black resist layer also requires high heat resistance and low dielectric properties to directly apply to a TFT substrate. However, it is noted that the conventional acryl or cardo-based black resist has a fatal problem that the permittivity control is difficult and the decomposition occurs in high temperature process.

Therefore, it is urgent to develop a novel black resist composition having high heat resistance and low dielectric properties, which is suitable for a novel structure such as a liquid crystal display, cover glass-integrated touch panel, OLED and flexible display, to which COT process is applied.

### DISCLOSURE

### Technical Problem

An object of the present invention is to provide a polysilsesquioxane resin composition and a black resist composition for light shielding comprising the same.

Another object of the present invention is to provide a polysilsesquioxane resin composition and a black resist composition for light shielding comprising the same, which are excellent in heat resistance in subsequent deposition or annealing process at a high temperature and are directly applicable to an electrode substrate or a TFT substrate and have a low dielectric property.

The other objects and advantages of the present invention will become more apparent from the following detailed description of the invention and claims.

### Technical Solution

Examples of the present invention will now be described more fully hereinafter with reference to the accompanying drawings, in which exemplary embodiments of the invention are shown. These examples are provided so that this disclosure will be thorough and complete, and will fully convey the scope of the invention to those skilled in the art. It is not limited to the example. Rather, these examples are provided so that this disclosure will be more thorough and complete, and will fully convey the concept of the invention to those skilled in the art.

In addition, a thickness and a size of each layer in the drawings are exaggerated for convenience and clarity of description, and the same reference numerals refer to the same elements in the drawings. As used herein, the term “and/or” includes anyone and all combinations of at least one among the listed items.

The terms of this specification are used for the purpose of describing specific embodiments only and are not intended to limit the invention. As used herein, a singular form may include a plurality of shapes, unless the context clearly dictates otherwise. Also, when used in this specification, the word “comprise” and/or “comprising” include is to specify the presence of stated features, numbers, steps, operations, members, elements and/or groups thereof, but does not preclude the presence or addition of other features, numbers, operations, members, elements and/or groups.

In the present invention, “alkyl” means a monovalent substituent derived from a linear or branched saturated hydrocarbon having 1 to 40 carbon atoms. Examples thereof include methyl, ethyl, propyl, isobutyl, sec-butyl, pentyl, iso-amyl and hexyl, but are not limited thereto.

In the present invention, “alkenyl” means a monovalent substituent derived from a linear or branched unsaturated hydrocarbon having 2 to 40 carbon atoms and at least one carbon-carbon double bond. Examples thereof include vinyl, allyl, isopropenyl, 2-butenyl, etc. but are not limited thereto.

In the present invention, “alkynyl” means a monovalent substituent derived from a linear or branched unsaturated hydrocarbon having 2 to 40 carbon atoms and at least one carbon-carbon triple bond. Examples thereof include ethynyl, 2-propynyl, etc. but are not limited thereto.

In the present invention, “aryl” means a monovalent substituent derived from an aromatic hydrocarbon having 6 to 60 carbon atoms in which a single ring or at least two rings are combined. Also, forms in which two or more rings are pendant or condensed with each other may be included. Examples of the aryl include phenyl, naphthyl, phenanthryl, anthryl, etc. but are not limited thereto.

In the present invention, “heteroaryl” means a monovalent substituent derived from a monoheterocyclic or a polyheterocyclic aromatic hydrocarbon having 5 to 40 nuclear atoms. At least one, preferably one to three of the carbons in the ring is substituted with a heteroatom such as N, O, S or Se. In addition, forms in which two or more rings are pendant or condensed with each other, and further condensed with an aryl group may be included. Examples of the heteroaryls include 6-membered monocyclic rings such as pyridyl, pyrazinyl, pyrimidinyl, pyridazinyl, triazinyl; polycyclic ring such as phenoxathienyl, indolizinyl, indolyl purinyl, quinolyl, benzothiazole, carbazolyl; and 2-furanyl, N-imidazolyl, 2-isoxazolyl, 2-pyridinyl, 2-pyrimidinyl, etc. but are not limited thereto.

In one embodiment of the present invention, the present invention relates to a polysilsesquioxane random copolymer comprising a heterocyclic structure represented by the following Formula 1:

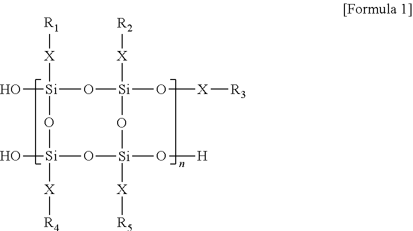

where X is selected from the group consisting of linear or branched C₁₋₂₀ alkylene group, C₁₋₂₀ alkenylene group, C₁₋₂₀ alkynylene group, C₆₋₁₈ arylene group, oxa group and carbonyl group,

R₁ to R₅ are the same as or different from each other, and each independently selected from the group consisting of hydrogen, deuterium, linear or branched C₁₋₂₀ alkyl group, C₁₋₂₀ alkenyl group, C₃₋₄₀ cycloalkyl group, heterocycloalkyl group having nuclear atoms of 3 to 40, heterocycloalkenyl group having nuclear atoms of 3 to 40, C₆₋₁₈ aryl group and an heteroaryl group having nuclear atoms of 5 to 60,

the alkyl group, the alkenyl group, the alkynyl group, the cycloalkyl group, the heterocycloalkyl group, the heterocycloalkenyl group, the aryl group, the carbonyl group, and heteroaryl group are each independently selected from the group consisting of deuterium, halogen, hydroxy, —CN, linear or branched C₁₋₁₂ alkyl group, C₁₋₆ alkoxy group, carbonyl group, amine group, isocyanate group, sulfonic acid group, C₆₋₁₈ aryl group, —N₃, —CONH₂, —OR′, —NR′R″, —SH and —NO₂, and at this time when substituted with a plurality of substituents, they may be the same or different from each other, the R′ and R″ are selected from the group consisting of hydrogen, deuterium, linear or branched C₁₋₁₂ alkyl group, C₁₋₁₂ alkenyl group, C₃₋₄₀ cycloalkyl group, heterocycloalkyl group having nuclear atoms of 3 to 40, heterocycloalkenyl group having nuclear atoms of 3 to 40, C₆₋₁₈ aryl group and heteroaryl group having nuclear atoms of 5 to 60.

Specifically, the polysilsesquioxane random copolymer having high heat resistance of the Formula 1 is prepared by copolymerization by sol-gel reaction of an organosilane monomer containing two or more heterocycles and is a random copolymer which is not limited to the order of arrangement of the respective polymerized units. More specifically, it is a compound represented by the following Formula 2, but it is not limited to the examples.

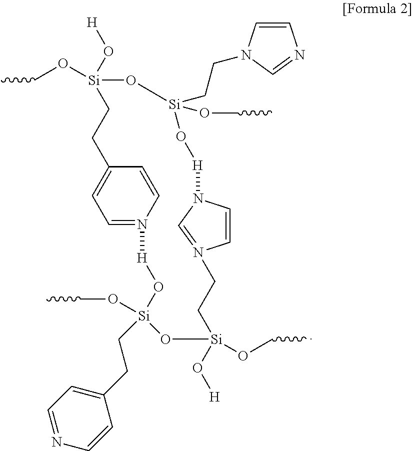

In one embodiment of the present invention, R₁ to R₅ may be selected from the group consisting of C₁₋₆ alkylcarbonyl group, C₁₋₂₀ linear or branched alkyl group and C₆₋₁₈ aryl group, and

the alkylcarbonyl group, alkyl group and aryl group is selected from the group consisting of linear or branched C₁₋₁₂ alkyl, C₁₋₁₂ alkenyl group, heterocycloalkenyl group having nuclear atoms of 3 to 40, C₆₋₁₈ aryl group and heteroaryl group having nuclear atoms of 5 to 60, sulfonic acid group, C₆₋₁₈ aryl group, —N₃, —CONH₂, —OR′, —NR′R″, —SH and —NO₂, and at this time when substituted with a plurality of substituents, they may be the same or different, the R′ and R″ are selected from the group consisting of hydrogen, deuterium, linear or branched C₁₋₁₂ alkyl group, C₁₋₁₂ alkenyl group, C₃₋₄₀ cycloalkyl group, heterocycloalkyl group having nuclear atoms of 3 to 40, heterocycloalkenyl group having nuclear atoms of 3 to 40, C₆₋₁₈ aryl group and heteroaryl group having nuclear atoms of 5 to 60.

In one embodiment of the present invention, R₁ to R₅ may be selected from the group consisting of the following substituents:

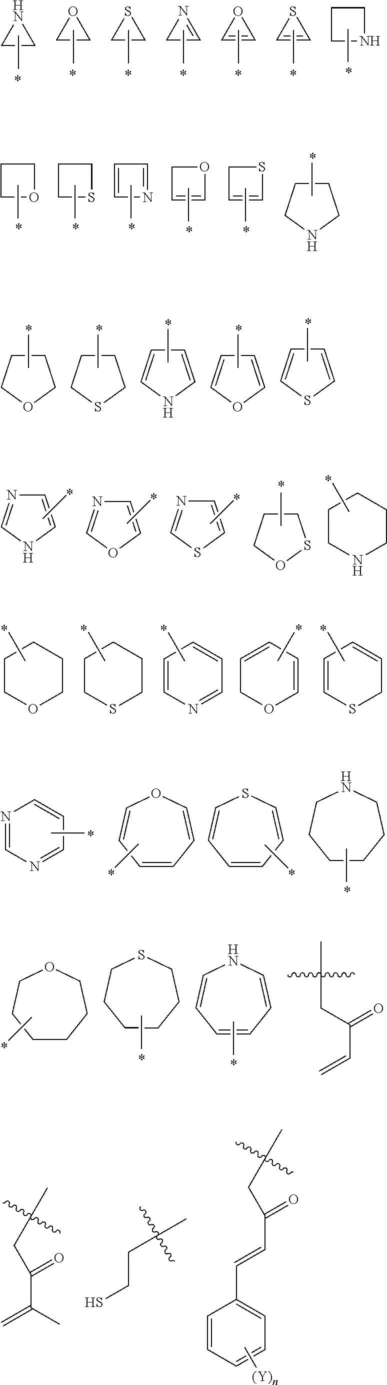

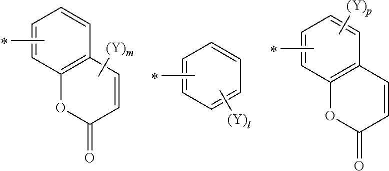

where, * denotes a binding site;

n is an integer of 1 to 5,

m is an integer of 1 or 2,

l is an integer of 1 to 5,

p is an integer of 1 to 3,

Y is selected from the group consisting of deuterium, C₁₋₁₂ alkyl, halogen, trifluoromethyl, hydroxy, aldehyde group, amine group, isocyanate group, —CN, sulfonic acid group, —N₃, —CONH₂, —OR′, —NR′R″, —SH and —NO₂, and the R′ and R″ are selected from the group consisting of hydrogen, deuterium, linear or branched C₁₋₁₂ alkyl group, C₁₋₂₀ alkenyl group, C₃₋₄₀ cycloalkyl group, heterocycloalkyl group having nuclear atoms of 3 to 40, heterocycloalkenyl group having nuclear atoms of 3 to 40, C₆₋₁₈ aryl group and heteroaryl group having nuclear atoms of 5 to 60.

Specifically, R₁ to R₅ are selected from the group consisting of oxiranyl, oxetanyl, aziridinyl, pyrrolidinyl, imidazolyl, oxazolyl, thiazolyl, pyrrolyl, furyl, thiophenyl, pyridinyl, azepanyl, azepinyl, cinnamoyl, coumarinyl, azidophenyl, acrylic group, methacrylic group, vinyl group and thiol group, but it is not limited to the examples. More specifically, R₁ to R₅ may be at least anyone selected from the group consisting of oxiranyl, oxetanyl and mixtures thereof so as to enable a thermal curing reaction in the hard bake process; may be at least anyone selected from the group consisting of aziridinyl, pyrrolidinyl, imidazolyl, oxazolyl, thiazolyl, pyrrolyl, furyl, thiophenyl, pyridinyl, azepanyl and azepinyl, so as to improve heat resistance by developing KOH or TMAH with dilute alkali due to polarity and forming hydrogen bond; may be at least one selected from the group consisting of cinnamoyl, coumarinyl, azidophenyl, acrylic group, methacryl group, vinyl group and thiol group which can form crosslinked bond by ultraviolet light; and may optionally comprise at least one selected from the group consisting of C₆₋₁₈ aryl group, C₆₋₁₈ cycloalkyl group and a cyclohexyl epoxy group, but is not limited to the example.

In one embodiment of the present invention, the polysilsesquioxane random copolymer according to the present invention has a weight average molecular weight (Mw) of 500 to 50,000 and a degree of dispersion of 1.0 to 10.0, and preferably a weight average molecular weight (Mw) of 1,000 to 15,000, and the degree of dispersion of 1.4 to 3.0. More preferably, the weight average molecular weight (Mw) is 2,000 to 8,000 and the degree of dispersion is 1.5 to 2.5.

In one embodiment of the present invention, a black resist composition for light-shielding comprises a polysilsesquioxane random copolymer of the Formula 1; a carbon black dispersion liquid; a photoinitiator; and an organic solvent, wherein the carbon black dispersion liquid is prepared by dispersing a carbon black pigment in the polysilsesquioxane random copolymer of the Formula 1 and coating it.

In one embodiment of the present invention, the present invention comprises 5 to 30 weight % of the polysilsesquioxane random copolymer; 2 to 65 weight % of the carbon black dispersion liquid; 0.1 to 4 weight % of the photoinitiator; and 1 to 82.9 weight % of the organic solvent.

In one embodiment of the present invention, carbon black is added into the polysilsesquioxane random copolymer solution of the Formula 1 for optical densities of the present invention, and is stirred in a beads mill apparatus for 10 to 14 hours to produce a colored dispersion.

In one embodiment of the present invention, the carbon black dispersion liquid of the present invention may be represented by the following Formula 9.

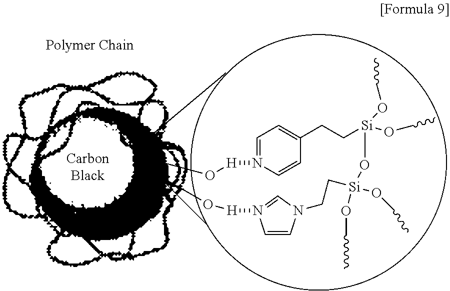

Specifically, the carbon black dispersion liquid represented by the Formula 9 has a polymer chain coated with the periphery of the carbon black, and the polymer chain is the polysilsesquioxane random copolymer of the above Formula 1. Namely, the carbon black pigment is coated with a polysilsesquioxane random copolymer of Formula 1 as a binder for dispersion. The carbon black pigment may be used in an amount of 10 to 300 parts by weight, preferably 50 to 200 parts by weight, more preferably 70 to 150 parts by weight, with respect of 100 parts by weight of the random copolymer represented by the Formula 1. When the carbon black pigment is in an amount less than 10 parts by weight, the optical density value is too low. When the carbon black pigment is in an amount more than 300 parts by weight, the sensitivity is too slow to form a pattern.

In one embodiment of the present invention, the carbon black pigment of the present invention is at least one selected from the group consisting of carbon black, titanium black, anilyl black and perylene black, but is not limited thereto.

In one embodiment of the present invention, the carbon black pigment of the present invention has an average particle diameter of 20 nm to 200 nm, preferably 30 nm to 100 nm, and more preferably 40 nm to 80 nm. When the average particle diameter is less than 20 nm, re-aggregation tends to occur and the light shielding property is poor. When the average particle diameter is more than 200 nm, the surface of the thin film after coating is irregular and it is difficult to form a fine pattern.

In one embodiment of the invention, the carbon black dispersion liquid of the present invention further comprises a surfactant, which is at least one selected from the group consisting of anionic surfactant, cationic surfactant, nonionic surfactant, amphiphilic surfactant, polyamine-based surfactant and polyester-based surfactant. Non-limiting examples include at least one among DISPER BYK-2001, DISPER BYK-2070, DISPER BYK-2118 (BYK), EFKA-4020, 4050, EFKA-4400, 4800 (BASF), but they are not limited to the examples. In addition, optionally pigment black 32 (perylene black) or pigment black 1 (aniline black) may be added for coloring aid.

In one embodiment of the present invention, the surfactant of the present invention comprises 0.01 to 10 weight % based on 100 weight % of the black resist composition for light shielding. If it is contained in an amount of less than 0.01 weight %, there arises a problem that the dispersion stability is decreased and if it exceeds 10 weight %, economical efficiency is deteriorated.

In one embodiment of the present invention, the photoinitiator of the present invention is a compound which forms a radical by ultraviolet rays to cause a crosslinking reaction. Preferably, it is at least one selected from the group consisting of alpha-hydroxy ketone-based compounds, phenylglyoxylate-based compounds, acylphosphine oxide-based compounds, alpha-amino ketone-based compounds, benzophenone-based compounds, benzyldimethylketal-based compounds and oxime ester-based compounds, and more preferably it is non-limiting one and more selected from Irgacure 184, Darocur 1173, Irgacure 127, Irgacure 2959, Irgacure 500, Irgacure 754, Darocur MBF, Lucirin TPO, Lucirin TPO-L, Irgacure 2100, Irgacure 819, Irgacure-DW, Darocur 4265, Irgacure 2022, Irgacure 907, Irgacure 369, Irgacure 1300, Irgacure 379, Darocur BP, Irgacure 651, Irgacure 784, Irgacure OXE 01 and Irgacure OXE 02, which are BASF's trade names.

In one embodiment of the present invention, the organic solvent comprised in the polysilsesquioxane resin composition of the present invention is selected from the group consisting of ethylene glycol dimethyl ether, diethylene glycol ethyl ether, diethylene glycol dimethylethyl ether, propylene glycol methyl ether, propylene glycol ethyl ether, propylene glycol propyl ether, dipropylene glycol methyl ether, methyl methoxypropionate, ethyl ethoxypropionate, ethyl lactate, methyl cellosolve acetate, ethyl cellosolve acetate, diethylene glycol methyl acetate, diethylene glycol ethyl acetate, methyl isobutyl ketone, cyclohexanone, N-methyl-2-pyrrolidone (NMP), diethylene glycol methyl ether, acetone, dimethylacetate, 2-(2-ethoxyethoxy) ethanol, 1,4-dioxane, toluene, xylene, gamma-butyrolactone and tetrahydrofuran, but is not limited to the examples.

In one embodiment of the present invention, a material for forming a black resist layer comprising a heterocyclic polysilsesquioxane copolymer resist composition of the present invention is a black matrix for a color filter or a color filter on a COT (color filter on A black matrix for a TFT process, a black bezel for a cover glass integrated touch panel, a light deflecting layer for protecting a pixel definition layer (Pixel Defined Layer) or an LTPS (low temperature polysilicon) or an oxide TFT (oxide TFT) A light blocking layer for a flexible display, a polarizing film replacement layer on various displays, and the present invention is not limited to this example.

### Advantageous Effects

The polysilsesquioxane random copolymer resin composition and the light-shielding black resist resin composition comprising the same according to the present invention can develop in various organic solvents and alkali aqueous solutions such as NaCO₃, KOH and TMAH (tetramethylammonium hydroxide), etc. after undergoing an ultraviolet exposure process, thereby forming a pattern for light shielding and realizing excellent optical density (OD), low dielectric constant and high resistance value.

In addition, the resistance even after post-process at 350° C. or more is excellent and the optical density (OD) or resistance value are not decreased due to hydrogen bonds between chains of heterocyclic structures and rigid structures, and therefore the black resist composition for light-shielding can applied to a black matrix for a color filter or a black matrix for a color filter of a liquid crystal display or a color filter on TFT (COT) process, which requires high heat resistance and low dielectric properties, a black bezel for cover glass-integrated touch panel, a pixel defined layer for OLED, an LTPS (low temperature polysilicon) or a light blocking layer for protecting an oxide TFT, a light blocking layer for a flexible display, a polarizing film replacement layer for upper on various displays.

### DESCRIPTION OF DRAWINGS

FIG. 1 illustrates the molecular weight of the polysilsesquioxane random copolymer according to Synthesis Example 1 of the present invention.

FIG. 2 illustrates the molecular weight of the polysilsesquioxane random copolymer according to Synthesis Example 2 of the present invention.

FIG. 3 illustrates the molecular weight of the polysilsesquioxane random copolymer according to Synthesis Example 3 of the present invention.

FIG. 4 illustrates the molecular weight of the polysilsesquioxane random copolymer according to Synthesis Example 4 of the present invention.

FIG. 5 illustrates the molecular weight of the polysilsesquioxane random copolymer according to Synthesis Example 5 of the present invention.

FIG. 6 is an SEM (scanning electron microscope) photograph showing the pattern resolution of the black resist composition for light-shielding of the present invention.

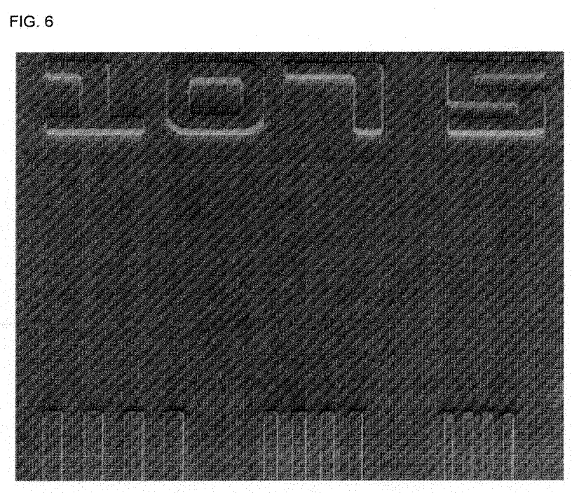

### BEST MODE

Hereinafter, examples of the present invention will be described in detail to understand the present invention. The present invention may, however, be embodied in many different forms and should not be limited to the embodiments set forth herein in order to clearly illustrate the present invention for those skilled in the art to which the present invention pertains.

### Synthesis Example 1

### Synthesis of Polysilsesquioxane Random Copolymer Containing Heterocycle 1

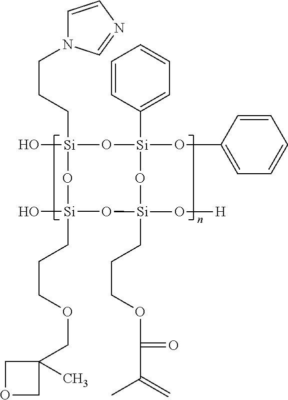

N-(trimethoxysilyl)propylimidazole of 80.92 g (0.30 mol), diphenyldimethoxysilane of 85.85 g (0.30 mol), triethoxy [3-[(3-ethyl-3-oxetanyl) methoxy] propyl] silane of 75.06 g (0.20 mol), 3-(trimethoxysilyl) propyl methacrylate of 58.17 g (0.20 mol) and propylene glycol monomethyl ether acetate of 200 g were weighed to prepare a solution and a mixture of 17 g of 35% aqueous HCl and 337 g of ultra-pure water was slowly added dropwise with stirring in a 2-L flask equipped with a funnel, a cooling tube and a stirrer. At this time, the temperature is maintained so that the exothermic temperature does not exceed 50° C. After completion of dropwise addition, the reaction temperature was raised to 80° C. and stirred for 24 hours.

After completion of the reaction, distilled water was added to recover the organic phase by phase separation, and residual solvent and water were removed by evaporation to obtain 120 g of polysilsesquioxane copolymer resin. The resulting copolymer resin was dissolved in 400 g of propylene glycol monomethyl ether acetate to prepare a resin solution having a solid content of 30%.

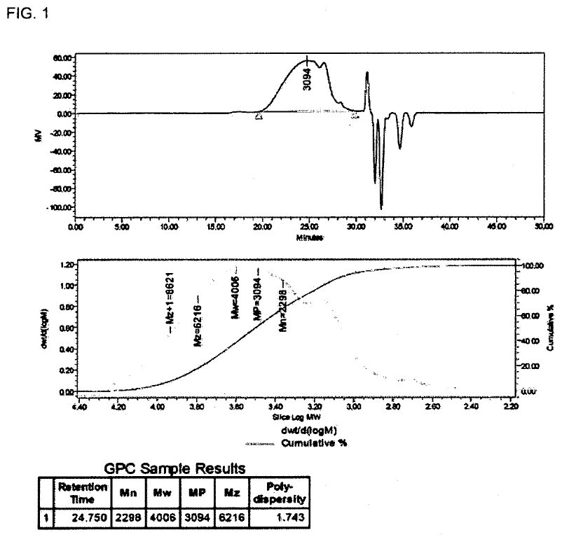

FIG. 1 shows the weight average molecular weight of the polysilsesquioxane random copolymer containing heterocycle prepared in Synthesis Example 1, and as a result of GPC measurement, the polydispersity index (PDI) of the copolymer resin was 1.74 and the weight average molecular weight (Mw) was of 4,000.

### Synthesis Example 2

### Synthesis of Polysilsesquioxane Random Copolymer Containing Heterocycles 2

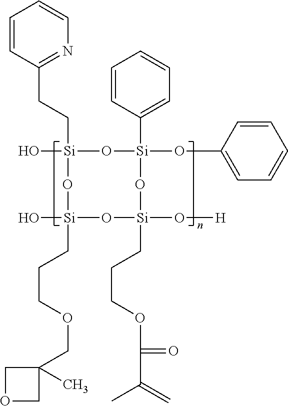

Triethoxy[2-(2-pyridyl)]ethyl]silane, 90.51 g (0.30 mol), diphenyldimethoxysilane of 82.09 g (0.30 mol), triethoxy[3-(3-ethyl-3-oxetanyl) methoxy] propyl] silane of 71.78 g (0.20 mol), 3-(trimethoxysilyl)propyl methacrylate of 55.62 g (0.20 mol) and propylene glycol monomethyl ether acetate of 200 g were weighed to prepare a solution and a mixture of 17 g of 35% aqueous HCl and 337 g of ultra-pure water was slowly added dropwise with stirring in a 2-L flask equipped with a funnel, a cooling tube and a stirrer. At this time, the temperature is maintained so that the exothermic temperature does not exceed 50° C. After completion of dropwise addition, the reaction temperature was raised to 80° C. and stirred for 24 hours.

After completion of the reaction, distilled water was added to recover the organic phase by phase separation, and residual solvent and water were removed by evaporation to obtain 110 g of polysilsesquioxane copolymer resin. The resulting copolymer resin was dissolved in 365 g of propylene glycol monomethyl ether acetate to prepare a resin solution having a solid content of 30%.

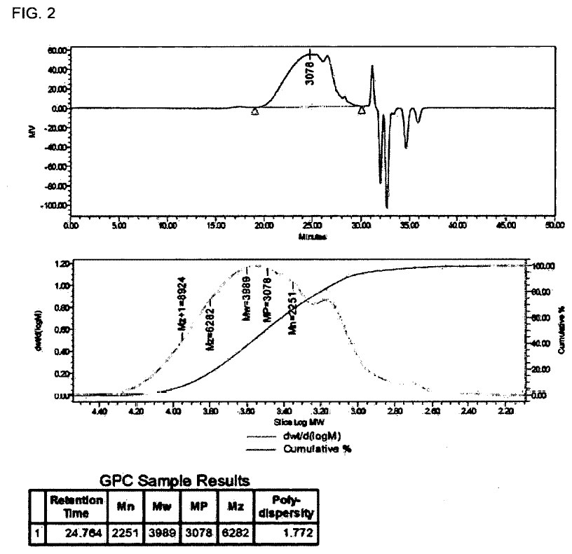

FIG. 2 shows the weight average molecular weight of the polysilsesquioxane random copolymer containing heterocycle prepared in Synthesis Example 2, and as a result of GPC measurement, the polydispersity index (PDI) of the copolymer resin was 1.77 and the weight average molecular weight (Mw) was of 3,990.

### Synthesis Example 3

### Synthesis of Polysilsesquioxane Random Copolymer Containing Heterocycles 3

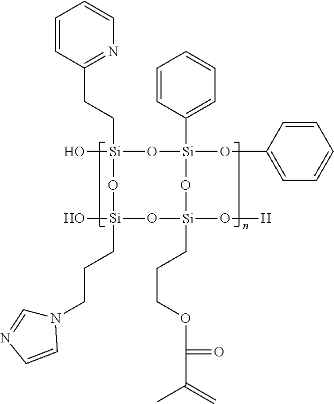

Triethoxy[2-(2-pyridyl)]ethyl]silane of 97.04 g (0.30 mol %), diphenyldimethoxysilane of 88.02 g (0.30 mol %), N-(trimethoxysilyl)propyl imidazole of 55.31 g (0.20 mol %), 3-(trimethoxysilyl)propyl methacrylate of 55.62 g (0.20 mol %) and propylene glycol monomethyl ether acetate of 200 g were weighed to prepare a solution and a mixture of 17 g of 35% aqueous HCl and 337 g of ultra-pure water was slowly added dropwise with stirring in a 2-L flask equipped with a funnel, a cooling tube and a stirrer. At this time, the temperature is maintained so that the exothermic temperature does not exceed 50° C. After completion of dropwise addition, the reaction temperature was raised to 80° C. and stirred for 24 hours.

After completion of the reaction, distilled water was added to recover the organic phase by phase separation, and residual solvent and water were removed by evaporation to obtain 110 g of polysilsesquioxane copolymer resin. The resulting copolymer resin was dissolved in 330 g of propylene glycol monomethyl ether acetate to prepare a resin solution having a solid content of 30%.

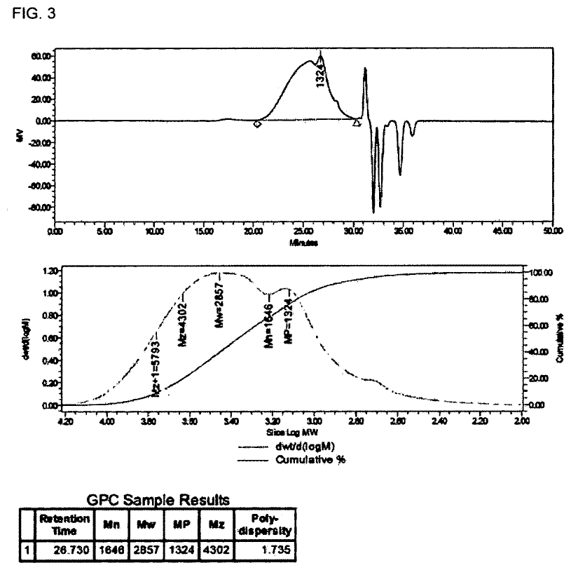

FIG. 3 shows the weight average molecular weight of the polysilsesquioxane random copolymer containing heterocycle prepared in Synthesis Example 3, and as a result of GPC measurement, the polydispersity index (PDI) of the copolymer resin was 1.74 and the weight average molecular weight (Mw) was of 2,860.

### Synthesis Example 4

### Synthesis of Polysilsesquioxane Random Copolymer Containing Heterocycle 4

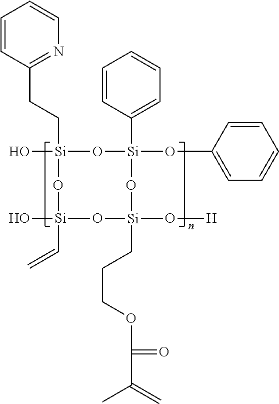

Triethoxy[2-(2-pyridyl)]ethyl]silane of 103.86 q (0.30 mol %). diphenyldimethoxysilane of 94.21 g (0.30 mol %), vinyltrimethoxysilane of 38.10 g (0.20 mol %), 3-(trimethoxysilyl)propyl methacrylate of 63.83 g (0.20 mol %) and propylene glycol monomethyl ether acetate of 200 g were weighed to prepare a solution and a mixture of 17 g of 35% aqueous HCl and 337 g of ultra-pure water was slowly added dropwise with stirring in a 2-L flask equipped with a funnel, a cooling tube and a stirrer. At this time, the temperature is maintained so that the exothermic temperature does not exceed 50° C. After completion of dropwise addition, the reaction temperature was raised to 80° C. and stirred for 24 hours.

After completion of the reaction, distilled water was added to recover the organic phase by phase separation, and residual solvent and water were removed by evaporation to obtain 115 g of polysilsesquioxane copolymer resin. The resulting copolymer resin was dissolved in 380 g of propylene glycol monomethyl ether acetate to prepare a resin solution having a solid content of 30%.

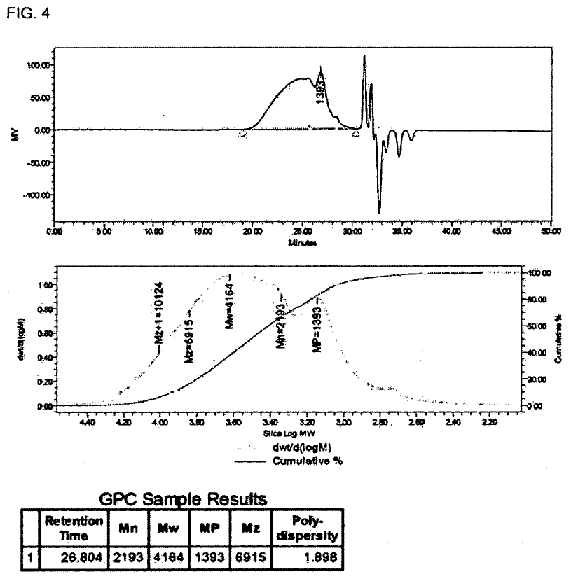

FIG. 4 shows the weight average molecular weight of the polysilsesquioxane random copolymer containing heterocycle prepared in Synthesis Example 4, and as a result of GPC measurement, the polydispersity index (PDI) of the copolymer resin was 1.90 and the weight average molecular weight (Mw) was of 4,160.

### Synthesis Example 5

### Synthesis of Polysilsesquioxane Random Copolymer Containing Heterocycle 5

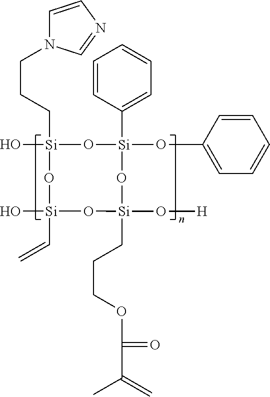

N-(trimethoxysilyl)propyl imidazole of 96.50 g (0.30 mol), diphenyldimethoxysilane of 99.19 g (0.30 mol %), vinyltrimethoxysilane of 40.11 g (0.20 mol %), 3-(trimethoxysilyl)propyl methacrylate of 67.20 g (0.20 mol %) and propylene glycol monomethyl ether acetate of 200 g were weighed to prepare a solution and a mixture of 17 g of 35% aqueous HCl and 337 g of ultra-pure water was slowly added dropwise with stirring in a 2-L flask equipped with a funnel, a cooling tube and a stirrer. At this time, the temperature is maintained so that the exothermic temperature does not exceed 50° C. After completion of dropwise addition, the reaction temperature was raised to 80° C. and stirred for 24 hours. After completion of the reaction, distilled water was added to recover the organic phase by phase separation, and residual solvent and water were removed by evaporation to obtain 125 g of polysilsesquioxane copolymer resin. The resulting copolymer resin was dissolved in 410 g of propylene glycol monomethyl ether acetate to prepare a resin solution having a solid content of 30%.

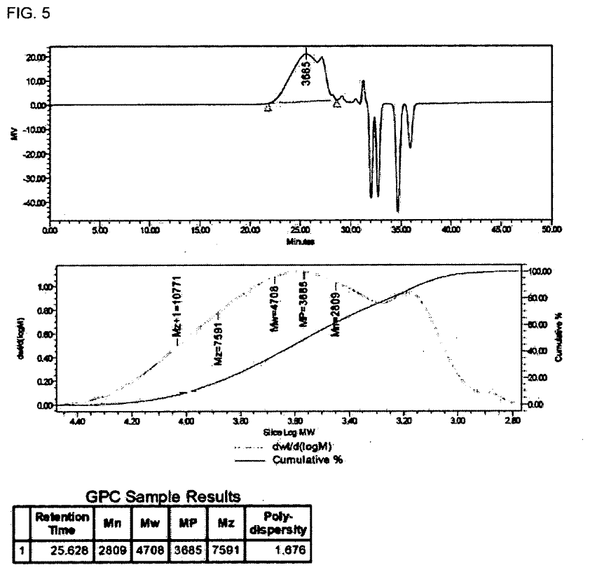

FIG. 5 shows the weight average molecular weight of the polysilsesquioxane random copolymer containing heterocycle prepared in Synthesis Example 5, and as a result of GPC measurement, the polydispersity index (PDI) of the copolymer resin was 1.68 and the weight average molecular weight (Mw) was of 4,710.

### Example 1

### Preparation of Polysilsesquioxane-Based Black Resist Resin Composition 1

A heterocycle-containing polysilsesquioxane random copolymer resin (weight average molecular weight 4,000) solution prepared in the Synthesis Example 1 of 100 parts by weight as a solid content fraction, a dispersion of carbon black coated with the copolymer resin (average particle diameter 80 nm, 30% solution) of 200 parts by weight as a solid content fraction, acylphosphine oxide (Trade name: Lucirin TPO, BASF) of 2 parts by weight and oxime ester (trade name: Irgacure OXE 02, BASF) of 1 part by weight as a photoinitiator and a silicone surfactant of 0.5 part by weight were diluted to 30 parts by weight of the solid content of the composition, by using propylene glycol monomethyl ether acetate as a diluting solvent and filtered through a pore size 2.0 μm PTFE membrane filter to obtain a liquid black resist resin composition.

### Example 2

### Preparation of Polysilsesquioxane-Based Black Resist Resin Composition 2

A polysilsesquioxane-based black resist resin composition was prepared in the same manner as in Example 1 by using a solution of the heterocyclic polysilsesquioxane random copolymer resin (weight average molecular weight: 3,990) prepared in the Synthesis Example 2 instead of the heterocyclic-containing polysilsesquioxane random copolymer resin prepared in the Synthesis Example 1.

### Example 3

### Preparation of Polysilsesquioxane-Based Black Resist Resin Composition 3

A polysilsesquioxane-based black resist resin composition was prepared in the same manner as in Example 1 by using a solution of the heterocyclic polysilsesquioxane random copolymer resin (weight average molecular weight: 2,860) prepared in the Synthesis Example 3 instead of the heterocyclic-containing polysilsesquioxane random copolymer resin prepared in the Synthesis Example 1.

### Example 4

### Preparation of Polysilsesquioxane-Based Black Resist Resin Composition 4

A polysilsesquioxane-based black resist resin composition was prepared in the same manner as in Example 1 by using a solution of the heterocyclic polysilsesquioxane random copolymer resin (weight average molecular weight: 4,160) prepared in the Synthesis Example 4 instead of the heterocyclic-containing polysilsesquioxane random copolymer resin prepared in the Synthesis Example 1.

### Example 5

### Preparation of Polysilsesquioxane-Based Black Resist Resin Composition 5

A polysilsesquioxane-based black resist resin composition was prepared in the same manner as in Example 1 by using a solution of the heterocyclic polysilsesquioxane random copolymer resin (weight average molecular weight: 4,710) prepared in the Synthesis Example 5 instead of the heterocyclic-containing polysilsesquioxane random copolymer resin prepared in the Synthesis Example 1.

### Comparative Example 1

A siloxane resin (Dow Corning's Xiameter RSN-0217, Mw 2,500) of 100 parts by weight as a solid content fraction Instead of the synthetic copolymer resin of the present invention, carbon black (average particle diameter 100 nm) of 100 parts by weight instead of a coloring dispersion of the present invention, acylphosphine oxide (Trade name: Lucirin TPO, BASF) of 2 parts by weight and oxime ester (trade name: Irgacure OXE 02, BASF) of 1 part by weight as a photoinitiator and a silicone surfactant of 0.5 part by weight were diluted to 30 parts by weight of the solid content of the composition, by using propylene glycol monomethyl ether acetate as a diluting solvent and filtered through a pore size 2.0 μm PTFE membrane filter to obtain a liquid black resist resin composition.

### Comparative Example 2

Poly(4-vinylphenyl-co-methylmethacrylate, Mw 8,000) acrylic copolymer of 100 parts by weight in a solid content faction instead of the synthetic copolymer resin of the present invention and carbon black (average particle diameter 100 nm) of 100 parts by weight instead of a coloring dispersion of the present invention, acylphosphine oxide (Trade name: Lucirin TPO, BASF) of 2 parts by weight and oxime ester (trade name: Irgacure OXE 02, BASF) of 1 part by weight as a photoinitiator and a silicone surfactant of 0.5 part by weight were diluted to 30 parts by weight of the solid content of the composition, by using propylene glycol monomethyl ether acetate as a diluting solvent and filtered through a pore size 2.0 μm PTFE membrane filter to obtain a liquid black resist resin composition.

The properties of the resin compositions of the above Examples and Comparative Examples were measured as described below, and the results are shown in Table 1 below.

<1. Coating Film Formation>

The black resist composition was spin-coated on a glass substrate at a speed of 1,000 rpm to form a film and then the film was baked in a soft baking process with a hot plate for 100, 120 seconds and the thickness of the coated film was measured by using an optical thickness meter (trade name: CAMAC ST-4000).

<2. Pattern Evaluation>

The resin composition was radiated by energy of 100 mJ/cm² (i-line 365 nm standard, initial 2.0 μm thick) using a mask aligner (product name: SUSS MA-6) with a 5 μm to 300 μm line & space 1:1 spacing photomask and G, H, I-line ultraviolet lamps, was developed in a 2.38% TMAH dilute alkali aqueous solution for 60 seconds, and washed with ultrapure water. The obtained pattern substrate was heated in an oven at 230° C. for 30 minutes. The silicon wafer or glass substrate on which the pattern was formed was observed with an electron microscope and when a 10 μm pattern was formed, it was determined to be “good”, and the sample which could not form the 10 μm pattern or had severe scum was determined to be “bad”.

<3. Residual Film Ratio Evaluation>

The residual film ratio was calculated by the following Equation 1:

Residual film ratio (%)=(film thickness after development and curing/initial thickness)×100 [Equation 1]

<4. Heat Resistance Evaluation>

After curing, thermogravimetric analysis (TGA, Perkin Elmer) was performed and a weight loss ratio according to temperature (loss wt %) was measured by increasing temperature at speed of 10° C./min from room temperature to 600° C. At this time, when the weight reduction rate at 400° C. was less than 10%, it was determined to be “good”, “normal” for 10% to 40%, and “bad” for more than 40%.

<5. Chemical Resistance Evaluation>

After forming a coating film, the film was cured and then immersed in a PR stripping solution (trade name, LT-360) 40° C. for 10 minutes, and the rate of swelling change of film thickness was calculated. A swelling of less than 5% was determined “good” and a swelling of at least 5% was determined “bad”.

<6. Dielectric Constant Evaluation>

After forming a coating film on an ITP substrate, the film was cured and a metal-insulator-metal (MIM) evaluation cell was fabricated by depositing a 1.0-diameter aluminum electrode thereon. In order to measure the dielectric constant, the capacitance (C) of the coated resist film of the evaluation cell was measured using an LCR-meter (Agilent Co. 4284), and the dielectric constant was calculated by the following Equation 2.

In the following Equation 2, d=thickness of resist film, A=area of deposited electrode, ε₀ is a constant of dielectric constant of vacuum (8.855×10⁻¹² F/m) and ε is dielectric constant of the resist film to be obtained.

C=(ε₀εA)/d [Equation 2]

<7. Evaluation of Moisture Absorption Rate>

After forming a coating film, the film was cured and immersed in distilled water at room temperature for 72 hours, and the change rate of the film thickness swelling was calculated. It was determined to be “good” for swelling of less than 3% and “bad” for swelling of more than 3%.

<8. Sheet Resistance Measurement>

After forming a coating film, the film was cured and surface resistance value was measured using a high resistance meter of Keithley 6517B.

<9. Optical Density; O.D. Value Measurement>

After forming a coating film, the film was cured and O.D. value was measured using an instrument X-Rite 361T.

TABLE 1

| | | | | | | Moisture | | |
|---|---|---|---|---|---|---|---|---|
| | | Residual | Heat | Chemical | Dielectric | absorption | Sheet | O.D. |
| | pattern | film ratio | Resistance | resistance | constant | rate | resistance | (μm) |
| Example 1 | Good | 83 | Good | Good | 6.31 | Good | 3.5E+12 | 3.1 |
| Example 2 | Good | 84 | Good | Good | 6.54 | Good | 5.7E+12 | 3.2 |
| Example 3 | Good | 82 | Good | Good | 6.29 | Good | 4.2E+12 | 3.2 |
| Example 4 | Good | 85 | Good | Good | 6.43 | Good | 4.6E+12 | 3.1 |
| Example 5 | Good | 84 | Good | Good | 6.37 | Good | 3.9E+12 | 3.2 |
| Comparative | Bad | 71 | Bad | Bad | 42.5 | Bad | 5.6E+12 | 3.1 |
| Example 1 | | | | | | | | |
| Comparative | Bad | 65 | Bad | Bad | 45.8 | Bad | 7.1E+12 | 3.0 |
| Example 2 | | | | | | | | |

As indicated in the above Table 1, the black resist composition using the polysilsesquioxane random copolymer according to the present invention and the carbon black dispersion liquid prepared by dispersing and coating in the polysilsesquioxane random copolymer composition exhibited not only excellent heat resistance capable of withstanding in process at a high temperature but also excellent high residual film ratio, chemical resistance and pattern resolution, in contrast with the conventional black resist composition.

In addition, the resist film formed using the composition of the present invention exhibits low dielectric and high resistance characteristics and a high optical density value as compared with the comparative example so that a novel black resist having excellent reliability and high performance can be expected.

Therefore, the black resist film obtained from the composition of the present invention can be used for a black matrix for a color filter or a black matrix for a color filter on TFT (COT) process, a black bezel for a cover glass-integrated touch panel, a pixel defined layer for an OLED, a light-shielding layer for LTPS (Low-temperature polysilicon) or an oxide TFT, a light-shielding layer for a flexible display, and a polarizing film replacement layer on various displays.

### INDUSTRIAL APPLICABILITY

The present invention relates to a polysilsesquioxane resin composition and a black resist composition for light-shielding comprising the same and more specifically, to the black resist composition for light-shielding, which has excellent heat resistance in even post-process at a high temperature and low dielectric performance applicable to a color filter on TFT (COT) process, a cover glass-integrated touch panel, an OLED and a flexible display.

1. A polysilsesquioxane random copolymer comprising a heterocyclic structure represented by following Formula 1: 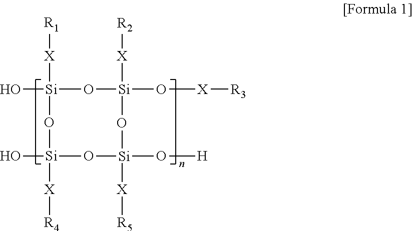
where X is selected from the group consisting of a bond, linear or branched C₁₋₂₀ alkylene group, C₁₋₂₀alkenylene group, C₁₋₂₀alkynylene group, C₆₋₁₈ arylene group, oxa group and carbonyl group,
R₁ to R₅ are the same as or different from each other and each independently selected from the group consisting of hydrogen, deuterium, linear or branched C₁₋₂₀ alkyl group, C₁₋₂₀ alkenyl group, carbonyl group, C₃₋₄₀cycloalkyl group, heterocycloalkyl group having nuclear atoms of 3 to 40, heterocycloalkenyl group having nuclear atoms of 3 to 40, C₆₋₁₈ aryl group and an heteroaryl group having nuclear atoms of 5 to 60,
the alkyl group, alkenyl group, alkynyl group, cycloalkyl group, heterocycloalkyl group, heterocycloalkenyl group, aryl group, carbonyl group, and heteroaryl group are each independently at least one selected from the group consisting of deuterium, halogen, hydroxy, —CN, linear or branched C₁₋₁₂ alkyl group, C₁₋₁₂ alkenyl group, C₁₋₆ alkoxy group, carbonyl group, amine group, isocyanate group, heterocycloalkenyl group having nuclear atoms of 3 to 40, sulfonic acid group, C₆₋₁₈ aryl group, —N₃, —CONH₂, —OR′, —NR′R″, —SH and —NO₂, and at this time when substituted with a plurality of substituents, they are the same as or different from each other, the R′ and R″ are selected from the group consisting of hydrogen, deuterium, linear or branched C₁₋₁₂ alkyl group, C₁₋₁₂ alkenyl group, C₃₋₄₀ cycloalkyl group, heterocycloalkyl group having nuclear atoms of 3 to 40, heterocycloalkenyl group having nuclear atoms of 3 to 40, C₆₋₁₈ aryl group and heteroaryl group having nuclear atoms of 5 to 60.

2. The polysilsesquioxane random copolymer of claim 1, R₁ to R₅ are selected from the group consisting of C₁₋₆ alkylcarbonyl group, linear or branched C₁₋₂₀ alkyl group and C₆₋₁₈ aryl group, and
the alkylcarbonyl group, alkyl group and aryl group are each independently at least one selected from the group consisting of linear or branched C₁₋₁₂ alkyl, C₁₋₂₀ alkenyl group, heterocycloalkenyl group having nuclear atoms of 3 to 40, sulfonic acid group, C₆₋₁₈ aryl group, —N₃, —CONH₂, —OR′, —NR′R″, —SH and —NO₂, and at this time when substituted with a plurality of substituents, they are the same as or different from each other, the R′ and R″ are selected from the group consisting of hydrogen, deuterium, linear or branched C₁₋₁₂ alkyl group, C₁₋₁₂ alkenyl group, C₃₋₄₀ cycloalkyl group, heterocycloalkyl group having nuclear atoms of 3 to 40, heterocycloalkenyl group having nuclear atoms of 3 to 40, C₆₋₁₈ aryl group and heteroaryl group having nuclear atoms of 5 to 60.

3. The polysilsesquioxane random copolymer of claim 1, wherein R₁ to R₅ are selected from the group consisting of: 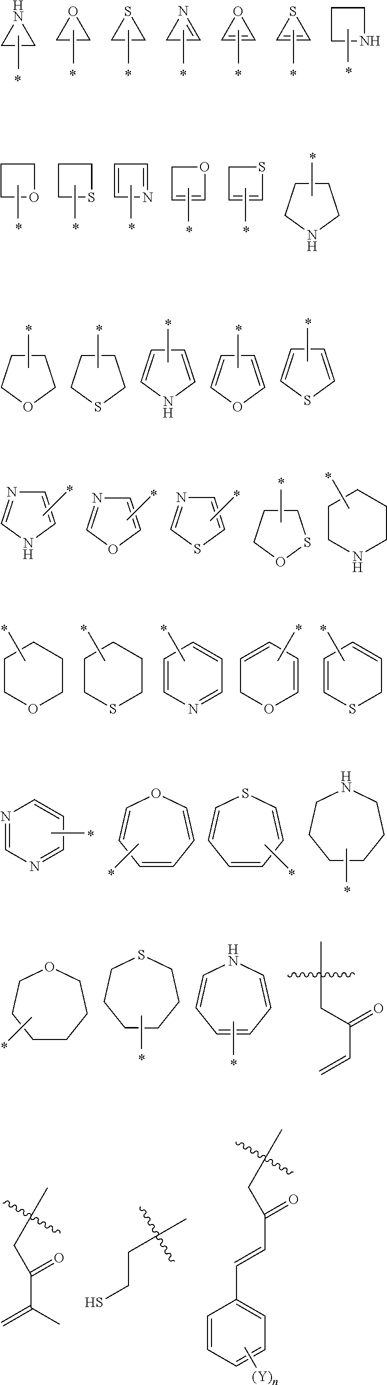 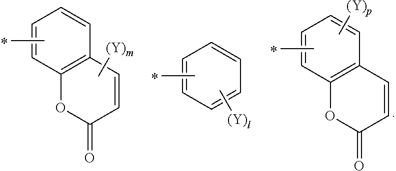
where, * denotes a binding site;
n is an integer of 1 to 5,
m is an integer of 1 or 2,
l is an integer of 1 to 5,
p is an integer of 1 to 3,
Y is at least one selected from the group consisting of deuterium, C₁₋₁₂ alkyl group, halogen, trifluoromethyl, hydroxy, aldehyde group, amine group, isocyanate group, —CN, sulfonic acid group, —N₃, —CONH₂, —OR′, —SH and —NO₂, and the R′ and R″ are selected from the group consisting of hydrogen, deuterium, linear or branched C₁₋₂₀ alkyl group, C₁₋₂₀ alkenyl group, C₃₋₄₀cycloalkyl group, heterocycloalkyl group having nuclear atoms of 3 to 40, heterocycloalkenyl group having nuclear atoms of 3 to 40, C₆₋₁₈ aryl group and heteroaryl group having nuclear atoms of 5 to 60.

4. The polysilsesquioxane random copolymer of claim 3, wherein R₁ to R₅ are at least one selected from the group consisting of oxiranyl, oxetanyl, aziridinyl, pyrrolidinyl, imidazolyl, oxazolyl, thiazolyl, pyrrolyl, furyl, thiophenyl, pyridinyl, azepanyl, azepinyl, cinnamoyl, coumarinyl, azidophenyl, acrylic group, methacrylic group, vinyl group and thiol group.

5. The polysilsesquioxane random copolymer of claim 1, which has a weight average molecular weight (Mw) of 500 to 50,000 and a polydispersity index of 1.0 to 10.0.

6. Black resist composition for light-shielding comprising:
a polysilsesquioxane random copolymer of claim 1;
a carbon black dispersion liquid;
a photoinitiator, and
an organic solvent,
wherein the carbon black dispersion liquid is prepared by dispersing and coating a carbon black pigment in the polysilsesquioxane random copolymer of claim 1.

7. The black resist composition for light-shielding of claim 6, which comprises the polysilsesquioxane random copolymer of 5 to 30 weight %;
the carbon black dispersion liquid of 2 to 65 weight %;
the photoinitiator of 0.1 to 4 weight %; and
the organic solvent of 1 to 82.9 weight %.

8. The black resist composition for light-shielding of claim 6, wherein the carbon black pigment is at least one selected from the group consisting of carbon black, titanium black, anilyl black and perylene black.

9. The black resist composition for light-shielding of claim 6, wherein the carbon black pigment has an average particle diameter of 20 nm to 200 nm.

10. The black resist composition for light-shielding of claim 6, wherein the carbon black dispersion liquid further comprises a surfactant and the surfactant is at least one selected from the group consisting of an anionic surfactant, a cationic surfactant, a nonionic surfactant, an amphoteric surfactant, a polyamine-based surfactant and a polyester-based surfactant.

11. The black resist composition for light-shielding of claim 10, wherein the surfactant comprises 0.01 to 10 weight % based on 100 weight % of the black resist composition for light-shielding.

12. An Interlayer insulating film for a display and a semiconductor comprising the black resist composition for light-shielding of claim 6.

13. A planarization film for a display and a semiconductor comprising the black resist composition for light-shielding of claim 6.

14. A passivation insulating film for a display and a semiconductor comprising the black resist composition for light-shielding of claim 6.

15. A light-shielding pattern layer for an OLED comprising the black resist composition for light-shielding of claim 6.

16. A pixel defining layer for an OLED comprising the black resist composition for light-shielding of claim 6.

17. A black matrix for a touch panel comprising the black resist composition for light-shielding of claim 6.

18. A black matrix for a liquid crystal display comprising the black resist composition for light-shielding of claim 6.
